(19) United States
(12) Patent Application Publication
(10) Pub. No.: US 2026/0149424 A1
(43) Pub. Date: May 28, 2026

(54) Audio input circuit capable of preventing deterioration of total harmonic distortion

(71) Applicant: REALTEK SEMICONDUCTOR CORPORATION, HSINCHU (TW)

(72) Inventors: LI-LUNG KAO, HSINCHU (TW); CHIH-HSIEN WANG, HSINCHU (TW)

(21) Appl. No.: 19/332,290

(22) Filed: Sep. 18, 2025

(30) Foreign Application Priority Data
Nov. 26, 2024 (TW) 113145623

(51) Int. Cl. H03F 3/45; H04R 3/00

(52) U.S. Cl. CPC H03F 3/45479; H04R 3/00; H03F 2200/03

(57) ABSTRACT

An audio input circuit includes a single-ended signal input circuit, a differential signal input circuit, a first amplifier circuit, and a second amplifier circuit. The single-ended signal input circuit is enabled by switches in a single-ended mode to output a single-ended audio signal to the first amplifier circuit. The differential signal input circuit is enabled by switches in a differential mode to output a differential audio signal to the first amplifier circuit. The first amplifier circuit outputs an inverted audio output signal to the second amplifier circuit according to signals it received. The second amplifier circuit outputs a non-inverted audio output signal according to signals it received. In the single-ended and differential modes, the signals inputted to non-inverting inputs of the first and second amplifier circuits are DC signals to stabilize the on-resistance linearity of the switches and prevent the deterioration of the audio input circuit's total harmonic distortion.

### BACKGROUND OF THE INVENTION

### 1. Field of the Invention

The present disclosure relates to an audio input circuit, especially to an audio input circuit capable of preventing the deterioration of the audio input circuit's total harmonic distortion.

### 2. Description of Related Art

FIG. 1 shows a conventional microphone signal input circuit. The microphone signal input circuit 10 of FIG. 1 can operate in a single-ended mode, a differential mode, or a mixed-signal mode by means of the setting of switches.

As shown in FIG. 1, the microphone signal input circuit 10 includes: a first path mainly composed of a first resistor 112 and a first switch 114, the first path configured to be enabled in the single-ended mode and the mixed-signal mode to receive a single-ended signal VP2; a second path mainly composed of a second resistor 122 and a second switch 124, the second path configured to be enabled in the single-ended mode and the mixed-signal mode to receive a direct current (DC) signal VDC; a third path mainly composed of a third resistor 132 and a third switch 134, the third path configured to be enabled in the differential mode and the mixed-signal mode to receive a non-inverting component VP1 of a differential signal; a fourth path mainly composed of a fourth resistor 142 and a fourth switch 144, the fourth path configured to be enabled in the differential mode and the mixed-signal mode to receive an inverting component VN1 of the differential signal; an amplifier 150 including an inverting input terminal, a non-inverting input terminal, an inverting output terminal, and a non-inverting output terminal, wherein the inverting input terminal is coupled to the first switch 114 and the third switch 134 to receive VP2 and/or VP1, the non-inverting input terminal is coupled to the second switch 124 and the fourth switch 144 to receive VDC and/or VN1, the inverting output terminal is used to output an inverting output signal VON, and the non-inverting output terminal is used to output a non-inverting output signal VOP; a first feedback resistor 160 coupled between the inverting input terminal and the inverting output terminal; and a second feedback resistor 170 coupled between the non-inverting input terminal and the non-inverting output terminal. It is noted that the designed resistance values of the first resistor 112 and the second resistor 122 are half of the designed resistance values of the other resistors.

FIG. 2 shows the microphone signal input circuit 10 operating in the single-ended mode, wherein each dotted arrow indicates the direction of a signal and each dotted sinewave stands for a signal. As shown in FIG. 2, in order to generate VON and VOP in the single-ended mode, both the inverting input and the non-inverting input of the amplifier 150 receive non-DC signal components, and this makes the linearity of the on-resistance Ron of the first switch 114 and the second switch 124 deteriorate and results in the deterioration of the microphone signal input circuit's total harmonic distortion (THD). Similar problems occur in the mixed-signal mode.

Based on the configuration of FIG. 1, the microphone signal input circuit 10 further includes the following problems:
(1) In the single-ended mode, if the gain of the amplifier 150 is changed due to the adjustment in the resistance value of the first feedback resistor 160, since both the non-inverting input and the inverting input of the amplifier 150 have signal components, the input resistance Rin of the microphone signal input circuit 10 changes with the change of the resistance value of the first feedback resistor 160; since the foregoing first path usually includes an alternating current (AC) coupling capacitor (not shown in the figure), the change of Rin means that the frequency response of the first path will change with the change of the gain of the amplifier 150, which causes the frequency response of the input of the microphone signal input circuit 10 to change. Similar problems occur in the mixed-signal mode.
(2) In the single-ended mode, the output offset of the amplifier 150 (i.e., the difference between VOP and VON) is related to the second resistor 122 and the first feedback resistor 160, and thus changes with the change of the gain of the amplifier 150, which causes the output quality of the microphone signal input circuit 10 to deteriorate. Similar problems occur in the mixed-signal mode.

### SUMMARY OF THE INVENTION

An objective of the present disclosure is to disclose an audio input circuit capable of preventing the problems of the prior art.

A first embodiment of the audio input circuit of the present disclosure can optionally operate in one of a single-ended mode and a differential mode. The first embodiment includes a single-ended signal input circuit, a differential signal input circuit, a first amplifier circuit, and a second amplifier circuit.

In the first embodiment, the single-ended signal input circuit includes a single-ended-circuit first resistor, a single-ended-circuit first switch, and a single-ended-circuit second switch. The single-ended-circuit first resistor is coupled between a single-ended-audio-signal input terminal and the single-ended-circuit first switch, wherein the single-ended-audio-signal input terminal is configured to receive a single-ended audio signal in the single-ended mode. The single-ended-circuit first switch is coupled between the single-ended-circuit first resistor and a first inverting input of a first amplifier of the first amplifier circuit, and is configured to be turned on in the single-ended mode. The single-ended-circuit second switch is coupled between a common-mode-signal input terminal and a first non-inverting input of the first amplifier, and is configured to be turned on in the single-ended mode, wherein the common-mode-signal input terminal is configured to receive a common-mode signal.

In the first embodiment, the differential signal input circuit includes a differential-circuit first resistor, a differential-circuit first switch, a differential-circuit second resistor, a differential-circuit second switch, and a differential-circuit third switch. The differential-circuit first resistor is coupled between a differential-audio-signal non-inverting input terminal and the differential-circuit first switch, wherein the differential-audio-signal non-inverting input terminal is configured to receive a non-inverted component of a differential audio signal in the differential mode. The differential-circuit first switch is coupled between the differential-circuit first resistor and the first inverting input of the first amplifier, and is configured to be turned on in the differential mode. The differential-circuit second resistor is coupled between a differential-audio-signal inverting input terminal and the differential-circuit second switch, wherein the differential-audio-signal inverting input terminal is configured to receive an inverted component of the differential audio signal in the differential mode, and the inverted component and the non-inverted component are complementary signals of the differential audio signal. The differential-circuit second switch is coupled between the differential-circuit second resistor and the differential-circuit third switch and is configured to be turned on in the differential mode. The differential-circuit third switch is coupled between the differential-circuit second switch and the first non-inverting input of the first amplifier and is configured to be turned on in the differential mode.

In the first embodiment, the first amplifier circuit includes the foregoing first amplifier and a feedback resistor. The first amplifier includes the first inverting input, the first non-inverting input, and a first output, wherein the first output is used to output an inverted audio output signal according to signals received by the first inverting input and the first non-inverting input. The first feedback resistor is coupled between the first inverting input and the first output. In the first embodiment, the second amplifier circuit includes an input resistor, a second feedback resistor, a second amplifier, and an output resistor. The input resistor is coupled between the first output of the first amplifier and a second inverting input of the second amplifier. The second feedback resistor has one end coupled to the input resistor and the second inverting input, and has another end coupled to a second output of the second amplifier and the output resistor. The second amplifier includes the second inverting input, a second non-inverting input, and the second output, wherein the second non-inverting input is configured to receive the common-mode signal, and the second output is used to output a non-inverted audio output signal according to signals received by the second inverting input and the second non-inverting input. The output resistor has one end coupled to the second output and another end coupled to the differential-circuit second switch and the differential-circuit third switch. It is noted that in the differential mode, an output component from the second output of the second amplifier offsets an output component from the differential-circuit second switch through the output resistor so that the first non-inverting input of the first amplifier receives a direct-current (DC) signal. Accordingly, the configuration of the audio input circuit of the first embodiment can stabilize the on-resistance linearity of the switches coupled to the first non-inverting input of the first amplifier in the single-ended mode and the differential mode to prevent the deterioration of the audio input circuit's total harmonic distortion.

A second embodiment of the audio input circuit of the present disclosure is configured to operate in a differential mode. The second embodiment includes the differential signal input circuit, the first amplifier circuit, and the second amplifier circuit of the foregoing first embodiment. It is noted that the switches of the above-mentioned circuits of the second embodiment can be replaced by transmission lines or kept conducting.

A third embodiment of the audio input circuit of the present disclosure is configured to operate in a mixed-signal mode. The third embodiment includes the single-ended signal input circuit, the differential signal input circuit, the first amplifier circuit, and the second amplifier circuit of the foregoing first embodiment. It is noted that the single-ended-circuit second switch of the above-mentioned circuits of the third embodiment can be removed or kept non-conducting while the other switches can be replaced by transmission lines or kept conducting. In the third embodiment, the single-ended signal input circuit further includes: a single-ended-circuit second resistor coupled between the common-mode-signal input terminal and the first non-inverting input of the first amplifier.

These and other objectives of the present invention will no doubt become obvious to those of ordinary skill in the art after reading the following detailed description of the preferred embodiments that are illustrated in the various figures and drawings.

### BRIEF DESCRIPTION OF THE DRAWINGS

FIG. 1 shows a conventional microphone signal input circuit.

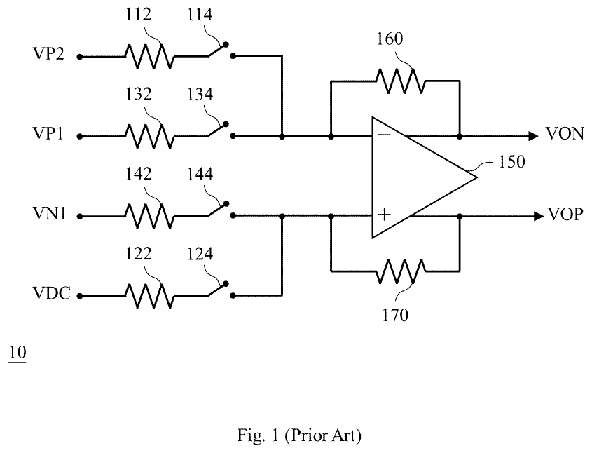

FIG. 2 shows the microphone signal input circuit of FIG. 1 operating in a single-ended mode.

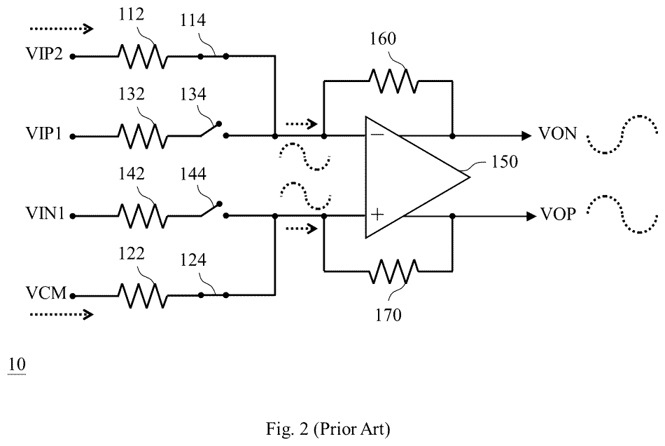

FIG. 3 shows an embodiment of the audio input circuit of the present disclosure.

FIG. 4 shows the audio input circuit of FIG. 3 operating in a single-ended mode.

FIG. 5 shows the audio input circuit of FIG. 3 operating in a differential mode.

FIG. 6 shows another embodiment of the audio input circuit of the present disclosure that can operate in a mixed-signal mode.

FIG. 7 shows a simplified circuit of the audio input circuit of FIG. 3 that can operate in a single-ended mode.

FIG. 8 shows a simplified circuit of the audio input circuit of FIG. 3 that can operate in a differential mode.

### DETAILED DESCRIPTION OF THE PREFERRED EMBODIMENTS

This specification discloses an audio input circuit. The configuration of the audio input circuit can stabilize the on-resistance linearity of the switches in the audio input circuit to prevent the deterioration of the total harmonic distortion (THD) of the audio input circuit. This audio input circuit can also prevent its input resistance Rin and output offset from changing with the change of the gain of the amplifier(s) of the audio input circuit.

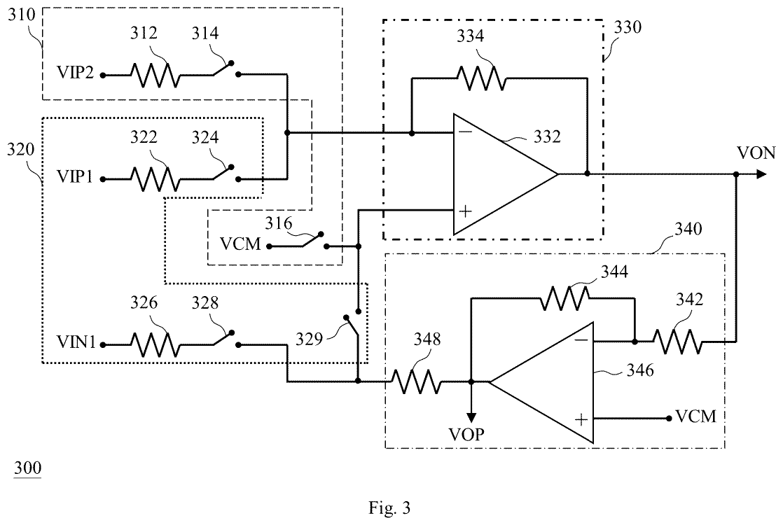

FIG. 3 shows an embodiment of the audio input circuit of the present disclosure. The audio input circuit 300 of FIG. 3 includes a single-ended signal input circuit 310, a differential signal input circuit 320, a first amplifier circuit 330, and a second amplifier circuit 340. The single-ended signal input circuit 310 is enabled through switches in a single-ended mode to output a signal to the first amplifier circuit 330. The first amplifier circuit 330 outputs an inverted audio output signal VON to the second amplifier circuit 340 according to the signals the first amplifier circuit 330 received. The second amplifier circuit 340 outputs a non-inverted audio output signal VOP according to the signals the second amplifier circuit 340 received. It is noted that in the single-ended mode and the differential mode, the signals received by the non-inverting inputs of the first amplifier circuit 330 and the second amplifier circuit 340 are direct current (DC) signals or the equivalent thereof (e.g., signals whose variations are negligible), which stabilize the on-resistance linearity of the switches in the audio input circuit 300 and prevent the deterioration of the total harmonic distortion of the audio input circuit 300.

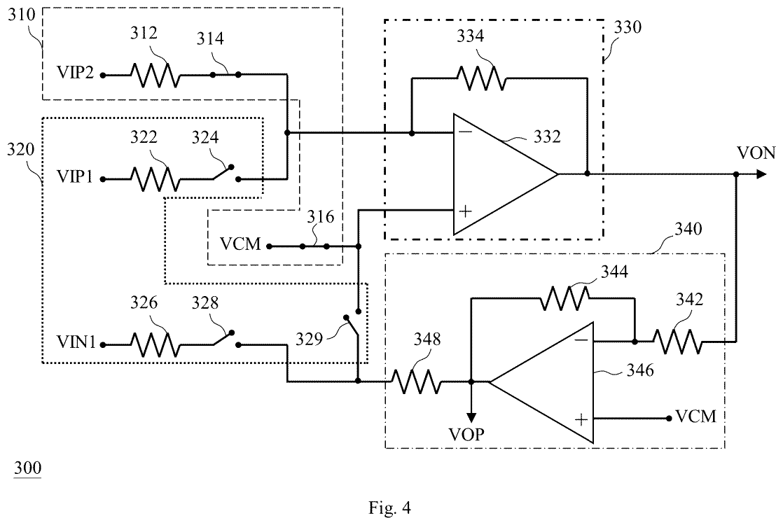

Referring to FIG. 3, the single-ended signal input circuit 310 includes a single-ended-circuit first resistor 312, a single-ended-circuit first switch 314, and a single-ended-circuit second switch 316. The single-ended-circuit first resistor 312 is coupled between a single-ended-audio-signal input terminal and the single-ended-circuit first switch 314, wherein the single-ended-audio-signal input terminal is used to receive a single-ended audio signal VIP2 in the single-ended mode. The single-ended-circuit first switch 314 is coupled between the single-ended-circuit first resistor 312 and a first inverting input of a first amplifier 332, and is used to be turned on in the single-ended mode. The single-ended-circuit second switch 316 is coupled between a common-mode-signal input terminal and a first non-inverting input of the first amplifier 332, and is used to be turned on in the single-ended mode, wherein the common-mode-signal input terminal is used to receive a common-mode signal VCM. FIG. 4 shows the audio input circuit 300 operating in the single-ended mode to help understanding, and the details are described in the later paragraphs.

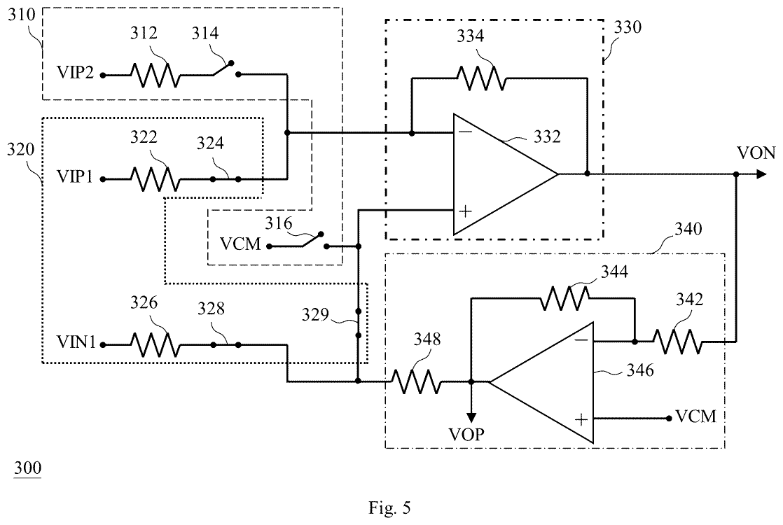

Referring to FIG. 3, the differential signal input circuit 320 includes a differential-circuit first resistor 322, a differential-circuit first switch 324, a differential-circuit second resistor 326, a differential-circuit second switch 328, and a differential-circuit third switch 329. The differential-circuit first resistor 322 is coupled between a differential-audio-signal non-inverting input terminal and the differential-circuit first switch 324, wherein the differential-audio-signal non-inverting input terminal is used to receive a non-inverted component VIP1 of a differential audio signal in the differential mode. The differential-circuit first switch 324 is coupled between the differential-circuit first resistor 322 and the first inverting input of the first amplifier 332, and is used to be turned on in the differential mode. The differential-circuit second resistor 326 is coupled between a differential-audio-signal inverting input terminal and the differential-circuit second switch 328, wherein the differential-audio-signal inverting input terminal is used to receive an inverted component VIN1 of the differential audio signal in the differential mode, and the inverted component VIN1 and the non-inverted component VIP1 are complementary signals of the differential audio signal. The differential-circuit second switch 328 is coupled between the differential-circuit second resistor 326 and the differential-circuit third switch 329, and is used to be turned on in the differential mode. The differential-circuit third switch 329 is coupled between the differential-circuit second switch 328 and the first non-inverting input of the first amplifier 332, and is used to be turned on in the differential mode. FIG. 5 shows the audio input circuit 300 operating in the differential mode to help understanding, and the details are described in the later paragraphs.

Referring to FIG. 3, the first amplifier circuit 330 includes a first amplifier 332 and a first feedback resistor 334. The first amplifier 332 includes the first inverting input, the first non-inverting input, and a first output, wherein the first output is used to output an inverted audio output signal VON according to the signals received by the first inverting input and the first non-inverting input. The first feedback resistor 334 is coupled between the first inverting input and the first output.

Referring to FIG. 3, the second amplifier circuit 340 includes an input resistor 342, a second feedback resistor 344, a second amplifier 346, and an output resistor 348. The input resistor 342 is coupled between the first output of the first amplifier 332 and a second inverting input of the second amplifier 346. One end of the second feedback resistor 344 is coupled to the input resistor 342 and the second inverting input, and the other end of the second feedback resistor 344 is coupled to a second output of the second amplifier 346 and the output resistor 348. The second amplifier 346 includes the second inverting input, a second non-inverting input, and the second output, wherein the second non-inverting input is used to receive the common-mode signal VCM, and the second output is used to output a non-inverted audio output signal VOP according to the signals received by the second inverting input and the second non-inverting input. One end of the output resistor 348 is coupled to the second output, and the other end of the output resistor 348 is coupled to the differential-circuit second switch 328 and the differential-circuit third switch 329.

FIG. 4 shows the audio input circuit 300 operating in the single-ended mode. As can be seen from FIG. 4, both the non-inverting input of the first amplifier 332 and the non-inverting input of the second amplifier 346 receive the common-mode signal VCM, and thus the on-resistance Ron of the single-ended circuit second switch 316 will not be affected by any varying signal component (e.g., alternating current (AC) signal component). This prevents the linearity degradation of the on-resistance Ron and ensures that the total harmonic distortion of the audio input circuit 300 in the single-ended mode is better than that of the prior art. Furthermore, since the VCM received by the non-inverting input of the first amplifier 332 is constant, the input resistance Rin observed from the perspective of the first amplifier 332 does not change with the change of the gain of the first amplifier circuit 330, that is, it does not change with the change of the resistance value of the first feedback resistor 334. In addition, each of the input signals VIP2, VIP1, and VIN1 can be a signal that passes through an alternating current (AC) coupling capacitor (not shown in the figure). Under the above circumstance (i.e., AC coupling input), the difference (i.e., −2 vos) between the non-inverted audio output signal VOP (equivalent to −vos that is equivalent to the signal at the inverting input of the first amplifier 332) and the inverted audio output signal VON (equivalent to vos) is a constant value, and consequently the output offset of the audio input circuit 300 (i.e., the difference between VOP and VON) does not change with the change of the gain of the first amplifier circuit 330, that is, it does not change with the change of the resistance value of the first feedback resistor 334.

FIG. 5 shows the audio input circuit 300 operating in the differential mode. As can be seen from FIG. 5, the output from the second output of the second amplifier 346 balances the output from the differential-circuit second switch 328 through the output resistor 348 so that the on-resistance Ron of the differential-circuit third switch 329 will not be affected by any varying signal component (that is, the signal received by the first non-inverting input of the first amplifier 332 is a DC signal or the equivalent thereof (e.g., a signal whose variation is negligible)), which prevents the linearity degradation of the on-resistance Ron. In addition, since the signal received by the non-inverting input of the first amplifier 332 is a DC signal or a similar, the input resistance Rin observed from the perspective of the first amplifier 332 does not change with the change of the gain of the first amplifier circuit 330, that is, it does not change with the change of the resistance value of the first feedback resistor 334.

In an implementation example of the audio input circuit 300, the audio input circuit 300 optionally includes a part or all of the following technical features:
(1) In either the single-ended mode or the differential mode, the single-ended-circuit first resistor 312, the differential-circuit first resistor 322, the differential-circuit second resistor 326, the first feedback resistor 334, and the output resistor 348 are the same type of resistors (e.g., P+ poly resistors) and may have the same resistance.
(2) Each of the single-ended-circuit first resistor 312, the differential-circuit first resistor 322, the differential-circuit second resistor 326, the first feedback resistor 334, and the output resistor 348 is a variable resistor.
(3) The input resistor 342 and the second feedback resistor 344 have the same resistance.
(4)When the single-ended mode is enabled, the differential mode is disabled, and the differential-circuit first switch 324, the differential-circuit second switch 328, and the differential-circuit third switch 329 are turned off to be non-conducting; and when the differential mode is enabled, the single-ended mode is disabled, and the single-ended-circuit first switch 314 and the single-ended-circuit second switch 316 are turned off to be non-conducting.
(5) Each of the single-ended audio signal and the differential audio signal is a microphone input signal.
(6) The audio input circuit 300 is applied to an audio codec.

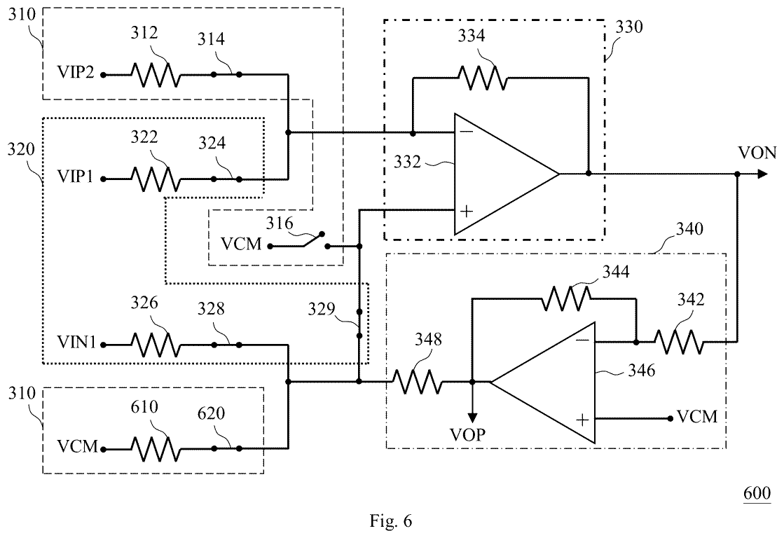

FIG. 6 shows another embodiment of the audio input circuit of the present disclosure that can operate in a mixed-signal mode. Compared with FIG. 3, the single-ended signal input circuit 310 of the audio input circuit 600 shown in FIG. 6 further includes a single-ended-circuit second resistor 610 (e.g., a variable resistor the same as the single-ended-circuit first resistor 312) and a single-ended-circuit third switch 620. The single-ended-circuit second resistor 610 is coupled between the common-mode signal input terminal and the single-ended-circuit third switch 620. The single-ended-circuit third switch 620 is coupled between the single-ended-circuit second resistor 610 and the differential-circuit third switch 329, and is used to be turned on in the mixed-signal mode. Referring to FIG. 6, in the mixed-signal mode, the single-ended-circuit first switch 314, the single-ended-circuit third switch 620, the differential-circuit first switch 324, the differential-circuit second switch 328 and the differential-circuit third switch 329 are turned on to be conducting, and the single-ended-circuit second switch 316 is turned off to be non-conducting. When the audio input circuit 600 is dedicated to the mixed-signal mode, the single-ended-circuit second switch 316 can be removed or kept non-conducting while the other switches can be replaced by transmission lines or kept conducting.

In an implementation example of the audio input circuit 600, the audio input circuit 600 includes the following technical features: in the mixed-signal mode, each of the single-ended-circuit first resistor 312 and the single-ended-circuit second resistor 610 has a first resistance value, each of the differential-circuit first resistor 322, the differential-circuit second resistor 326, the first feedback resistor 334, and the output resistor 348 has a second resistance value, and the first resistance value is half of the second resistance value. It is noted that the implementation of the present invention is not limited to the above features as long as such implementation is practicable.

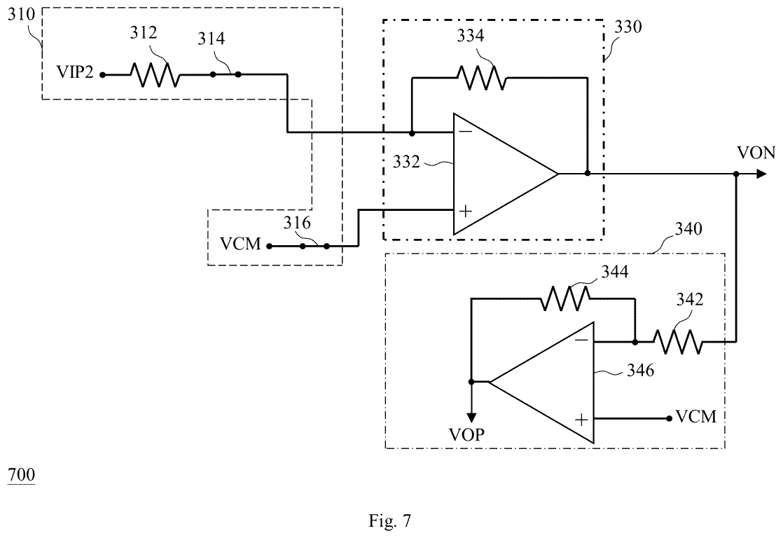

When the audio input circuit 300 of FIG. 3 is dedicated to the single-ended mode, the audio input circuit 300 can be simplified as the audio input circuit 700 of FIG. 7, wherein the single-ended-circuit first switch 314 and the single-ended-circuit second switch 316 are kept conducting. The audio input circuit 700 can be further simplified, if practicable. For example, both the single-ended-circuit first switch 314 and the single-ended-circuit second switch 316 are replaced by transmission lines.

Since a person having ordinary skill in the art can appreciate the details and modifications of the embodiment of FIG. 7 by referring to the description of the embodiments of FIGS. 3-6, repeated and redundant descriptions are omitted here.

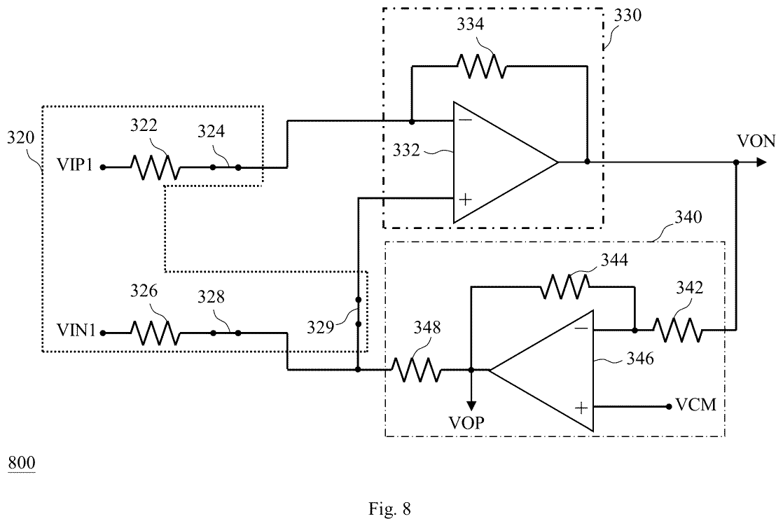

When the audio input circuit 300 of FIG. 3 is dedicated to the differential mode, the audio input circuit 300 can be simplified as the audio input circuit 800 of FIG. 8, wherein the differential-circuit first switch 324, the differential-circuit second switch 328, and the differential-circuit third switch 329 are kept conducting. The audio input circuit 800 can be further simplified, if practicable. For example, the differential-circuit first switch 324, the differential-circuit second switch 328, and the differential-circuit third switch 329 are all replaced by transmission lines.

Since a person having ordinary skill in the art can appreciate the details and modifications of the embodiment of FIG. 8 by referring to the description of the embodiments of FIGS. 3-6, repeated and redundant descriptions are omitted here.

It is noted that people having ordinary skill in the art can selectively use some or all of the features of any embodiment in this specification or selectively use some or all of the features of multiple embodiments in this specification to implement the present invention as long as such implementation is practicable; in other words, the present invention can be implemented flexibly in accordance with the present disclosure.

To sum up, the audio input circuit of the present disclosure can prevent the on-resistance linearity of the switches of the audio input circuit from deteriorating and thereby prevent the deterioration of the total harmonic distortion of the audio input circuit. In addition, the audio input circuit of the present disclosure can prevent its input resistance Rin and output offset from changing with the change of the gain of the amplifier(s) of the audio input circuit.

The aforementioned descriptions represent merely the preferred embodiments of the present invention, without any intention to limit the scope of the present invention thereto. Various equivalent changes, alterations, or modifications based on the claims of the present invention are all consequently viewed as being embraced by the scope of the present invention.

What is claimed is:

1. An audio input circuit comprising a single-ended signal input circuit, a differential signal input circuit, a first amplifier circuit, and a second amplifier circuit, wherein:
the single-ended signal input circuit includes a single-ended-circuit first resistor, a single-ended-circuit first switch, and a single-ended-circuit second switch, wherein:
the single-ended-circuit first resistor is coupled between a single-ended-audio-signal input terminal and the single-ended-circuit first switch, and the single-ended-audio-signal input terminal is configured to receive a single-ended audio signal in a single-ended mode;
the single-ended-circuit first switch is coupled between the single-ended-circuit first resistor and a first inverting input of a first amplifier of the first amplifier circuit and is configured to be turned on in the single-ended mode; and
the single-ended-circuit second switch is coupled between a common-mode-signal input terminal and a first non-inverting input of the first amplifier and is configured to be turned on in the single-ended mode, and the common-mode-signal input terminal is configured to receive a common-mode signal;
the differential signal input circuit includes a differential-circuit first resistor, a differential-circuit first switch, a differential-circuit second resistor, a differential-circuit second switch, and a differential-circuit third switch, wherein:
the differential-circuit first resistor is coupled between a differential-audio-signal non-inverting input terminal and the differential-circuit first switch, and the differential-audio-signal non-inverting input terminal is configured to receive a non-inverted component of a differential audio signal in a differential mode;
the differential-circuit first switch is coupled between the differential-circuit first resistor and the first inverting input of the first amplifier and is configured to be turned on in the differential mode;
the differential-circuit second resistor is coupled between a differential-audio-signal inverting input terminal and the differential-circuit second switch, the differential-audio-signal inverting input terminal is configured to receive an inverted component of the differential audio signal in the differential mode, and the inverted component and the non-inverted component are complementary signals of the differential audio signal;
the differential-circuit second switch is coupled between the differential-circuit second resistor and the differential-circuit third switch and is configured to be turned on in the differential mode; and
the differential-circuit third switch is coupled between the differential-circuit second switch and the first non-inverting input of the first amplifier and is configured to be turned on in the differential mode;
the first amplifier circuit includes the first amplifier and a feedback resistor, wherein:
the first amplifier includes the first inverting input, the first non-inverting input, and a first output, and the first output is used to output an inverted audio output signal according to signals received by the first inverting input and the first non-inverting input; and
the first feedback resistor is coupled between the first inverting input and the first output;
the second amplifier circuit includes an input resistor, a second feedback resistor, a second amplifier, and an output resistor, wherein:
the input resistor is coupled between the first output of the first amplifier and a second inverting input of the second amplifier;
the second feedback resistor has one end coupled to the input resistor and the second inverting input, and has another end coupled to a second output of the second amplifier and the output resistor;
the second amplifier includes the second inverting input, a second non-inverting input, and the second output, the second non-inverting input is configured to receive the common-mode signal, and the second output is used to output a non-inverted audio output signal according to signals received by the second inverting input and the second non-inverting input; and
the output resistor has one end coupled to the second output, and has another end coupled to the differential-circuit second switch and the differential-circuit third switch; and
in the differential mode, an output component from the second output of the second amplifier offsets an output component from the differential-circuit second switch through the output resistor so that the first non-inverting input of the first amplifier receives a DC signal.

2. The audio input circuit of claim 1, wherein in any one of the single-ended mode and the differential mode, the single-ended-circuit first resistor, the differential-circuit first resistor, the differential-circuit second resistor, the first feedback resistor, and the output resistor are the same type of resistors.

3. The audio input circuit of claim 1, wherein each of the single-ended-circuit first resistor, the differential-circuit first resistor, the differential-circuit second resistor, the first feedback resistor, and the output resistor is a variable resistor.

4. The audio input circuit of claim 1, wherein the input resistor and the second feedback resistor have the same resistance.

5. The audio input circuit of claim 1, wherein:
when the single-ended mode is enabled, the differential mode is disabled and the differential-circuit first switch, the differential-circuit second switch, and the differential-circuit third switch are turned off; and
when the differential-mode is enabled, the single-ended mode is disabled, and the single-ended-circuit first switch and the single-ended-circuit second switch are turned off.

6. The audio input circuit of claim 1, wherein each of the single-ended audio signal and the differential audio signal is a microphone input signal.

7. The audio input circuit of claim 1, wherein the single-ended signal input circuit further includes:
a single-ended-circuit second resistor coupled between the common-mode-signal input terminal and a single-ended-circuit third switch; and
the single-ended-circuit third switch coupled between the single-ended-circuit second resistor and the differential-circuit third switch, and configured to be turned on in a mixed-signal mode,
wherein in the mixed-signal mode, the single-ended-circuit first switch, the differential-circuit first switch, the differential-circuit second switch, and the differential-circuit third switch are turned on while the single-ended-circuit second switch is turned off.

8. The audio input circuit of claim 7, wherein in the mixed-signal mode, each of the single-ended-circuit first resistor and the single-ended-circuit second resistor has a first resistance value, each of the differential-circuit first resistor, the differential-circuit second resistor, the first feedback resistor, and the output resistor has a second resistance value, and the first resistance value is half the second resistance value.

9. The audio input circuit of claim 1, wherein the audio input circuit is applied to an audio codec.

10. An audio input circuit configured to operate in a differential mode, the audio input circuit comprising a differential signal input circuit, a first amplifier circuit, and a second amplifier circuit, wherein:
the differential signal input circuit includes:
a differential-circuit first resistor coupled between a differential-audio-signal non-inverting input terminal and a first inverting input of a first amplifier of the first amplifier circuit, wherein the differential-audio-signal non-inverting input terminal is configured to receive a non-inverted component of a differential audio signal; and
a differential-circuit second resistor coupled between a differential-audio-signal inverting input terminal and a first non-inverting input of the first amplifier, wherein the differential-audio-signal inverting input terminal is configured to receive an inverted component of the differential audio signal, and the inverted component and the non-inverted component are complementary signals of the differential audio signal;
the first amplifier circuit includes:
the first amplifier including the first inverting input, the first non-inverting input, and a first output, wherein the first output is used to output an inverted audio output signal according to signals received by the first inverting input and the first non-inverting input; and
a first feedback resistor coupled between the first inverting input and the first output; and
the second amplifier circuit includes:
an input resistor coupled between the first output of the first amplifier and a second inverting input of a second amplifier of the second amplifier circuit;
a second feedback resistor having one end coupled to the input resistor and the second inverting input, and having another end coupled to a second output of the second amplifier and an output resistor of the second amplifier circuit;
the second amplifier including the second inverting input, a second non-inverting input, and the second output, wherein the second non-inverting input is configured to receive a common-mode signal, and the second output is used to output a non-inverted audio output signal according to signals received by the second inverting input and the second non-inverting input; and
the output resistor having one end coupled to the second output, and having another end coupled to the differential-circuit second resistor and the first non-inverting input of the first amplifier; and
an output component from the second output of the second amplifier offsets an output component from the differential-circuit second resistor through the output resistor so that the first non-inverting input of the first amplifier receives a DC signal.

11. The audio input circuit of claim 10, wherein the differential-circuit first resistor, the differential-circuit second resistor, the first feedback resistor, and the output resistor are the same type of resistors.

12. The audio input circuit of claim 10, wherein each of the differential-circuit first resistor, the differential-circuit second resistor, the first feedback resistor, and the output resistor is a variable resistor.

13. The audio input circuit of claim 10, wherein the input resistor and the second feedback resistor have the same resistance.

14. The audio input circuit of claim 10, wherein the differential audio signal is a microphone input signal.

15. An audio input circuit configured to operate in a mixed-signal mode, the audio input circuit comprising a single-ended signal input circuit, a differential signal input circuit, a first amplifier circuit, and a second amplifier circuit, wherein:
the single-ended signal input circuit includes:
a single-ended-circuit first resistor coupled between a single-ended-audio-signal input terminal and a first inverting input of a first amplifier of the first amplifier circuit, wherein the single-ended-audio-signal input terminal is configured to receive a single-ended audio signal; and
a single-ended-circuit second resistor coupled between a common-mode-signal input terminal and a first non-inverting input of the first amplifier, wherein the common-mode-signal input terminal is configured to receive a common-mode signal;
the differential signal input circuit includes:
a differential-circuit first resistor coupled between a differential-audio-signal non-inverting input terminal and the first inverting input of the first amplifier, wherein the differential-audio-signal non-inverting input terminal is configured to receive a non-inverted component of a differential audio signal; and
a differential-circuit second resistor coupled between a differential-audio-signal inverting input terminal and the first non-inverting input of the first amplifier, wherein the differential-audio-signal inverting input terminal is configured to receive an inverted component of the differential audio signal, and the inverted component and the non-inverted component are complementary signals of the differential audio signal;
the first amplifier circuit includes:
the first amplifier including the first inverting input, the first non-inverting input, and a first output, wherein the first output is used to output an inverted audio output signal according to signals received by the first inverting input and the first non-inverting input; and
a first feedback resistor coupled between the first inverting input and the first output; and
the second amplifier circuit includes:
an input resistor coupled between the first output of the first amplifier and a second inverting input of a second amplifier of the second amplifier circuit;
a second feedback resistor having one end coupled to the input resistor and the second inverting input, and having another end coupled between a second output of the second amplifier and an output resistor of the second amplifier circuit;
the second amplifier including the second inverting input, a second non-inverting input, and the second output, wherein the second non-inverting input is configured to receive the common-mode signal, and the second output is used to output a non-inverted audio output signal according to signals received by the second inverting input and the second non-inverting input; and
the output resistor having one end coupled to the second output, and having another end coupled to the single-ended-circuit second resistor, the differential-circuit second resistor, and the first non-inverting input of the first amplifier.

16. The audio input circuit of claim 15, wherein each of the single-ended-circuit first resistor and the single-ended-circuit second resistor has a first resistance value, each of the differential-circuit first resistor, the differential-circuit second resistor, the first feedback resistor, and the output resistor has a second resistance value, and the first resistance value is half the second resistance value.

17. The audio input circuit of claim 15, wherein each of the single-ended-circuit first resistor, the single-ended-circuit second resistor, the differential-circuit first resistor, the differential-circuit second resistor, the first feedback resistor, and the output resistor is a variable resistor.

18. The audio input circuit of claim 15, wherein the input resistor and the second feedback resistor have the same resistance.

19. The audio input circuit of claim 15, wherein each of the single-ended audio signal and the differential audio signal is a microphone input signal.

20. The audio input circuit of claim 15, wherein the audio input circuit is applied to an audio codec.
